(19) United States
(12) Patent Application Publication
(10) Pub. No.: US 2018/0171482 A1
(43) Pub. Date: Jun. 21, 2018

(54) METHOD FOR MANUFACTURING WIRING PATTERN, METHOD FOR MANUFACTURING CONDUCTIVE FILM, AND METHOD FOR MANUFACTURING TRANSISTOR

(71) Applicant: NIKON CORPORATION, Tokyo (JP)

(72) Inventors: Shohei KOIZUMI, Atsugi (JP); Yusuke KAWAKAMI, Yokohama (JP)

(73) Assignee: NIKON CORPORATION, Tokyo (JP)

(21) Appl. No.: 15/895,626

(22) Filed: Feb. 13, 2018

Related U.S. Application Data
(63) Continuation of application No. PCT/JP2016/073459, filed on Aug. 9, 2016.

(30) Foreign Application Priority Data
Aug. 19, 2015 (JP) 2015-161699

(51) Int. Cl. C23C 18/16; C23C 18/18; H05K 3/18; H05K 3/24; H01L 51/00

(52) U.S. Cl. CPC C23C 18/1662; C23C 18/1841; C23C 18/1653; H01L 51/0021; C23C 18/1608; H05K 3/244; H05K 3/184

(57) ABSTRACT

It is an object to provide a technique for obtaining a wiring pattern by electroless plating without using a lift-off process. A method for manufacturing a wiring pattern characteristically includes: a base layer forming step of forming an base layer including a catalyst for electroless plating and a resin; a surface layer removing step of removing at least a part of a surface layer of the base layer; and a plating layer forming step of performing electroless plating and forming a plating layer on the base layer subjected to the surface layer removing step.

### TECHNICAL FIELD

The present invention relates to a method for manufacturing a wiring pattern, a method for manufacturing a conductive film, and a method for manufacturing a transistor. The present invention claims the priority of Japanese Patent Application No. 2015-161699 filed on Aug. 19, 2015, the content of which is incorporated by reference herein as to designated states that accept incorporation by reference to literatures.

### BACKGROUND ART

Methods of using electroless plating in the manufacture of wiring patterns are known (for example, Patent Literature 1).

### CITATION LIST

### Patent Literature

Patent Literature 1: JP 2009-224705 A

### SUMMARY OF INVENTION

### Technical Problem

However, in accordance with the conventional methods, wiring patterns are formed by a lift-off process with the use of a resist material, and the wiring materials formed on the resist, which are to be removed, have been discarded together with the resist.

An object of the present invention is to provide a technique for obtaining a wiring pattern by electroless plating without using a lift-off process.

### Solution to Problem

An aspect of the present invention is a method for manufacturing a wiring pattern, which includes: a base layer forming step of forming an base layer including a catalyst for electroless plating and a resin; a surface layer removing step of removing at least a part of a surface layer of the base layer; and a plating layer forming step of performing electroless plating and forming a plating layer on the base layer subjected to the surface layer removing step, and the method is characterized in that a precursor for the resin is water-soluble.

Another aspect of the present invention is a method for manufacturing a conductive film, characterized in that the conductive film is manufactured by the above-described method for manufacturing a wiring pattern.

Yet another aspect of the present invention is a method for manufacturing a transistor including a gate electrode, a source electrode, a drain electrode, a semiconductor layer, and a gate insulating layer, characterized in that at least one of the gate electrode, the source electrode, and the drain electrodes is manufactured by the above-described method for manufacturing a wiring pattern.

### BRIEF DESCRIPTION OF DRAWINGS

FIG. 1 is a cross-sectional view for explaining an example of a method for manufacturing a wiring pattern according to a first embodiment.

FIG. 2 is a cross-sectional view (part 1) for explaining an example of a method for manufacturing a transistor according to a second embodiment.

FIG. 3 is a cross-sectional view (part 2) for explaining an example of the method for manufacturing a transistor according to the second embodiment.

FIG. 4 is a diagram illustrating an example of a transistor according to a third embodiment.

FIG. 5 is a cross-sectional view (part 1) for explaining an example of a method for manufacturing a transistor according to a fourth embodiment.

FIG. 6 is a cross-sectional view (part 2) for explaining an example of the method for manufacturing a transistor according to the fourth embodiment.

FIG. 7 is a cross-sectional view (part 3) for explaining an example of the method for manufacturing a transistor according to the fourth embodiment.

FIG. 8A and FIG. 8B is a diagram showing optical microscopic images of a plating base layer according to Example 1.

FIG. 9A and FIG. 9B is a diagram showing optical microscopic images of a plated wiring part according to Example 1.

FIG. 10A and FIG. 10B is a diagram showing optical microscopic images of a plated wiring part according to Comparative Example 1.

FIG. 11 is a diagram showing an optical microscopic image of a plated wiring part according to Example 2.

FIG. 12A and FIG. 12B is a diagram showing optical microscopic images of a substrate and a gate electrode according to Example 3.

FIG. 13A and FIG. 13B is a diagram showing the substrate after the formation of an insulator layer according to Example 3, and an optical microscopic image of the substrate.

FIG. 14A and FIG. 14B is a diagram showing the substrate after the formation of source and drain electrodes according to Example 3, and an optical microscopic image of the electrodes.

FIG. 15A and FIG. 15B is a diagram showing the substrate after the formation of an organic semiconductor layer according to Example 3, and an optical microscopic image of the substrate.

FIG. 16A and FIG. 16B is a diagram showing characteristic evaluations of a transistor according to Example 3.

### DESCRIPTION OF EMBODIMENTS

### First Embodiment

An example of an embodiment of the present invention will be described below with reference to the drawings.

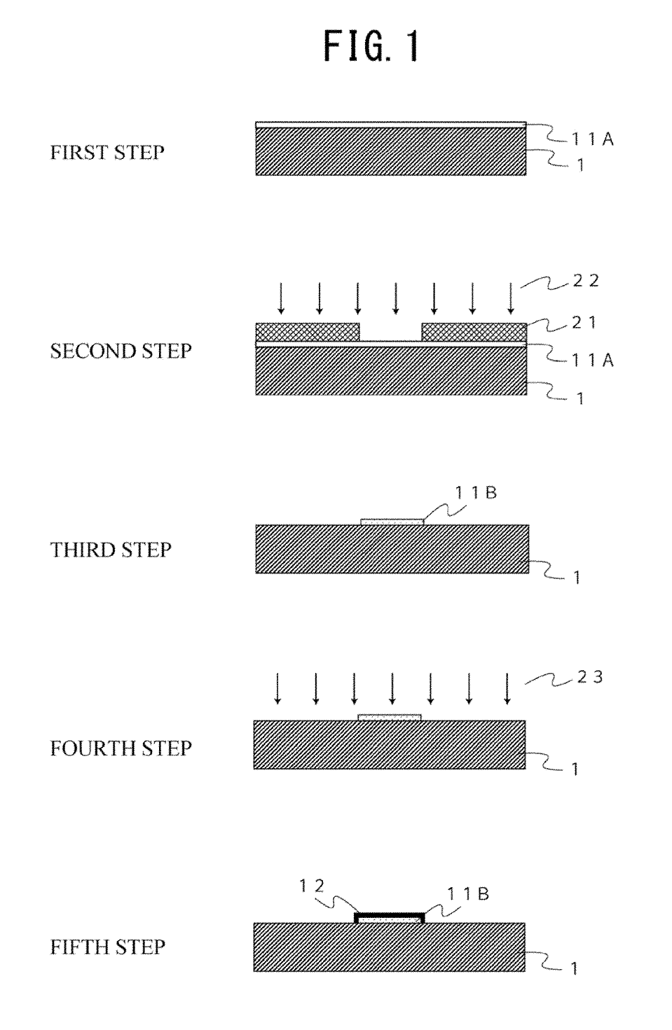

FIG. 1 is a cross-sectional view for explaining an example of a method for manufacturing a wiring pattern according to a first embodiment.

(First Step)

First, a substrate 1 is prepared. Commonly used substrate materials can be used for the substrate 1. For example, glass, polyethylene terephthalate (PET), polyethylene naphthalate (PEN), polyether sulfone (PES), polyetherimide, polyether ether ketone, polyphenylene sulfide, polyarylate, polyimide, polycarbonate (PC), cellulose triacetate (TAC), cellulose acetate propionate (CAP), and the like can be used.

In addition, a plating base layer solution 11A is prepared. The plating base layer solution 11A is a solution in which a precursor for a photosensitive resin and metal particles as a catalyst for electroless plating are dispersed in a solvent. The catalyst for electroless plating contains, for example, at least one of palladium, copper, nickel, iron, platinum, silver, ruthenium, rhodium, and the like. The average particle size of the catalyst for electroless plating can be, for example, 10 nm or less. It is to be noted that the average particle size is a value that can be obtained by adopting a volume average particle diameter, an area average particle diameter, a cumulative median diameter (Median diameter), or the like, with a known method such as a dynamic light scattering method as a measurement principle.

It is to be noted that the resin for use in the plating base layer solution 11A may be any resin as long as the resin is cured under predetermined conditions, and is not limited to any photosensitive resin. For example, the resin may be a thermosetting resin. A case where a photosensitive resin is used will be described below.

The plating base layer solution 11A is applied to the substrate 1. As a method for the application, commonly known methods can be used, such as spin coating, dip coating, spray coating, roll coating, die coating, brush coating, and printing methods, e.g., flexographic printing and screen printing. It is to be noted that before applying the plating base layer solution 11A, the substrate 1 may be irradiated with plasma using oxygen as a reaction gas under atmospheric pressure.

Thereafter, if necessary, a heat treatment is carried out to volatilize the solvent in the plating base layer solution 11A.

(Second Step)

Next, the plating base layer solution 11A is irradiated with ultraviolet rays 22 through a mask 21 formed so that the plating base layer solution 11A is cured into the shape of a desired wiring pattern. The part irradiated with the ultraviolet rays 22 is cured by exposure, because the plating base layer solution 11A includes a photosensitive resin. Regardless of whether the photosensitive resin for use in the plating base layer solution 11A is negative or positive, the solubility of the exposed part in a developer is increased when a positive photosensitive resin is used.

(Third Step)

Next, the uncured part is removed by bringing the plating base layer solution 11A, which has been partially cured, into contact with the developer, thereby providing a plating base layer 11B. As the developer, water, an organic solvent, or the like can be used. It is to be noted that the base layer solution removed can be used again as a base layer solution by appropriately adjusting the concentration of the solution with the use of an evaporator or the like.

(Fourth Step)

Next, at least a part of the surface layer in the plating base layer 11B is removed. The surface layer refers to a region including the surface of the plating base layer 11B. As a means for removing the surface layer, for example, the surface of the plating base layer 11B is irradiated with plasma 23 using oxygen as a reactive gas. Alternatively, for example, a part of the surface layer of the plating base layer 11B may be removed by bringing an alkaline solution into contact with the surface of the plating base layer 11B. The present step removes a part of the resin near the surface of the plating base layer 11B. Thereafter, if necessary, the surface of the plating base layer 11B is cleaned by means such as water washing.

(Fifth Step)

Next, a wiring is formed by forming an electroless plating layer 12 on the plating base layer 11B. As a method for forming the electroless plating layer 12, for example, a plating metal is deposited on the surface of the catalyst for electroless plating in the plating base layer 11B by immersing the substrate 1 in an electroless plating solution of nickel phosphorus, copper, tin, or the like.

The foregoing method can provide a wiring pattern suitable for a conductive film or a transistor. The removal of the resin in the vicinity of the surface in the plating base layer 11B in the fourth step improves the plating deposition property. This step also has the effect of removing residues after the development of the plating base layer solution 11A or the plating base layer 11B, thus improving the selectivity of plating, and allowing for wiring patterning in a more reliable manner. It is to be noted that in the first step, the plating base layer solution 11A may be applied after providing, on the substrate 1, a layer that changes the wettability of the surface of the substrate 1 in advance. For example, when a material including a water-soluble resin is used as a plating base layer solution, water is used as a developer for removing the uncured part, after curing the resin into a predetermined pattern. In this regard, when a hydrophilic film is provided in advance as a layer that changes the wettability, permeability of the part between residues and the substrate to the developer is increased, thereby making the residues more likely to peel off from the substrate, and the residues are thus removed in a more efficient manner. The material of the layer that changes the wettability may be determined appropriately depending on the substrate to be used, the plating base layer solution, the developer, and the like.

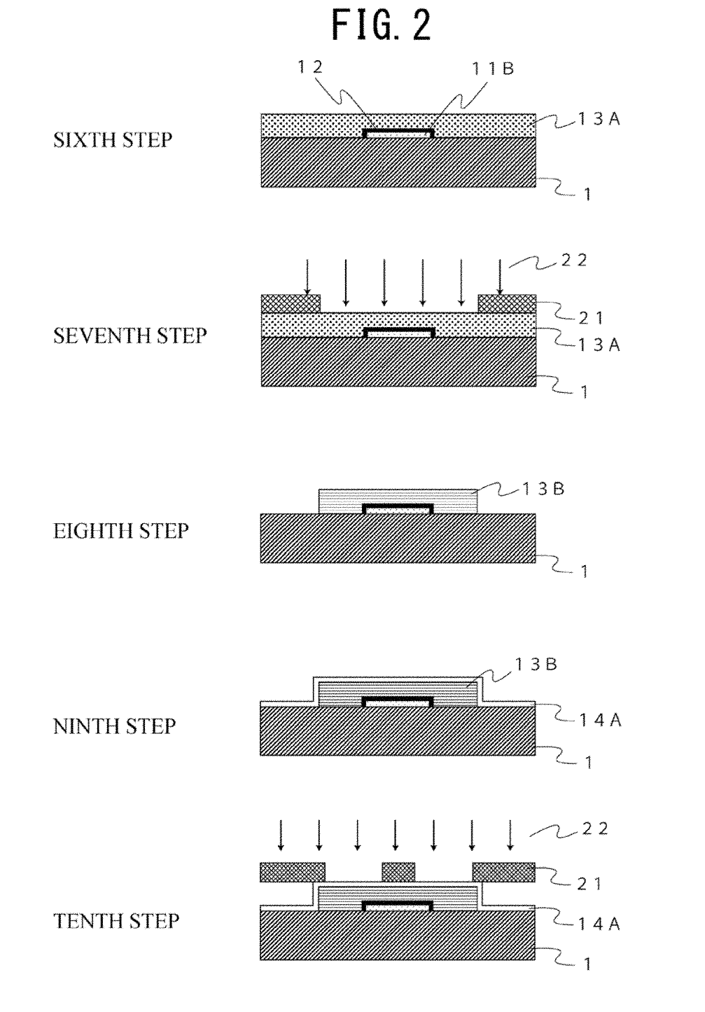

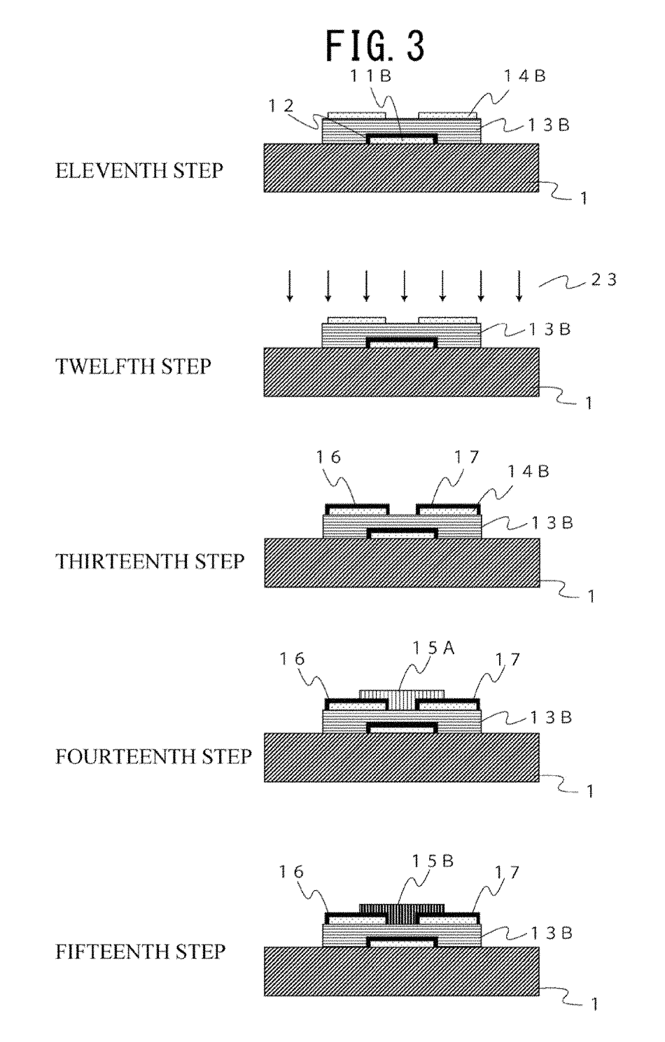

The foregoing steps make it possible to form a wiring pattern by electroless plating without using any lift-off process, thereby making it possible to reduce the wiring material to be discarded. In addition, it is possible to form a wiring pattern by a wet process, thus requiring no large-size vacuum equipment for use in a dry process such as vacuum deposition or sputtering. In addition, because no high-temperature process is required, a wiring pattern can be formed in a preferred manner even on a substrate such as a resin with a low softening point. It is to be noted that the wiring formed according to the present embodiment can be used as a gate electrode of a transistor. A method for manufacturing a transistor after forming a gate electrode according to the present embodiment will be described below with reference to FIGS. 2 and 3.

### Second Embodiment

FIG. 2 is a cross-sectional view (part 1) for explaining an example of a method for manufacturing a transistor according to a second embodiment. FIG. 3 is a cross-sectional view (part 2) for explaining an example of the method for manufacturing a transistor according to the second embodiment. The drawings are intended to explain a process for manufacturing a transistor after obtaining a gate electrode in accordance with the method for manufacturing a wiring pattern according to the first embodiment as shown in FIG. 1.

(Sixth Step)

Next, an insulator layer solution 13A is applied onto the substrate 1. For the insulator layer solution 13A, for example, a solution can be used, such as an ultraviolet curable acrylic resin, an ultraviolet curable epoxy resin, an ultraviolet curable ene/thiol resin, and an ultraviolet curable silicone resin. It is to be noted that the material that is used for the insulator layer is not limited to any ultraviolet curable resin material, as long as the material has only to be cured under certain conditions and has an insulating property. For example, a thermosetting resin material may be used in place of the ultraviolet curable resin material, but in the present embodiment, a case of using an ultraviolet curable resin material will be described.

(Seventh Step)

Next, the insulator layer solution 13A is irradiated with ultraviolet rays 22 through the mask 21, thereby providing the insulator layer solution 13A cured into a desired shape. In that regard, a heat treatment for accelerating the chemical reaction of the part irradiated with the ultraviolet rays 22 may be performed, if required.

(Eighth Step)

Next, the insulator layer of the uncured part is removed. For example, the immersion of the substrate 1 in a dissolving liquid removes the uncured insulator layer solution 13A, thereby providing the insulator layer 13B formed in a desired pattern. It is to be noted that even when a material such as a thermosetting resin is used as the insulator layer solution 13A, the application of heat to a predetermined part can provide the insulator layer 13B formed in a desired pattern.

(Ninth Step) to (Twelfth Step)

Next, the plating base layer solution 14A is applied to have an overlap with the insulator layer 13B. In the (ninth step) to (twelfth step), the plating base layer 14B subjected to patterning is formed in the same way as in the (first step) to (fourth step).

As a result of the twelfth step, at least a part of the surface layer of the plating base layer 14B subjected to patterning into a desired shape is removed.

(Thirteenth Step)

Next, wirings are formed to overlap with the plating base layer 14B. As in the fifth step, a plating metal is deposited on the surface of the catalyst for electroless plating in the plating base layer 11B, thereby providing metal wirings. Next, the metal wirings are immersed in a substitution gold plating bath, thereby depositing gold for substitution on the surfaces of the metal wirings. Next, the surfaces of the metal wirings are coated with gold of desired thickness by immersing the metal wirings in a reducing gold plating bath. The metal wirings obtained in this step can be used as the source electrode 16 and the drain electrode 17.

It is to be noted that the material that covers the metal wiring is not limited to gold, but a metal material is used which has a work function suitable for the HOMO/LUMO level of the material for use as a semiconductor. In the case of using a semiconductor material with a high HOMO level, such as pentacene, it is desirable to coat the metal wiring with gold. As a technique for obtaining a metal wiring from a metal laminated, there is a technique described in the International Publication WO 2013/024734 which is an application filed by the present applicant, and the description thereof will be thus omitted.

(Fourteenth Step)

Next, a solution 15A containing a semiconductor material is applied between the source electrode 16 and the drain electrode 17. While, for example, soluble pentacene represented by TIPS pentacene (6,13-Bis(triisopropylsilylethynyl)pentacene), organic semiconductors such as P3HT (poly(3-hexylthiophene-2,5-diyl)), zinc oxide (ZnO), inorganic semiconductors such as IGZO and carbon nanotubes, and the like can be used for the semiconductor material, an explanation will be given herein on the assumption that an organic semiconductor is used. The solution 15A containing a semiconductor material, obtained by dissolving an organic semiconductor in an organic solvent in which the organic semiconductor is soluble is applied between the source electrode 16 and the drain electrode 17.

(Fifteenth Step)

Next, the solvent in the solution 15A containing the semiconductor material is evaporated to obtain the organic semiconductor layer 15B. In this step, the organic semiconductor layer 15B may be obtained by natural drying with the substrate placed under normal temperature for a predetermined period of time, or the organic solvent may be evaporated by heating, thereby providing the organic semiconductor layer 15B.

It is to be noted that while the organic semiconductor layer 15B is formed by a wet process in this step, the method for forming the organic semiconductor layer 15B is not limited thereto, and for example, a sublimation method or a transfer method may be used.

In addition, in the case of heating the substrate 1, the substrate 1 is heated to a temperature equal to or lower than the softening point. Desirably, heating is performed under a temperature of 120° C. or lower. In this regard, the softening point herein refers to a temperature at which, when the substrate 1 is heated, the substrate 1 is softened to begin to undergo deformation, which can be obtained, for example, by a test method according to the JIS K 7207 (A method).

It is to be noted that even when heating is performed in any of the above-mentioned steps, the upper limit of the heating temperature is preferably the softening point of the substrate 1.

The present embodiment makes it possible to form the electrode of the transistor by electroless plating without using any lift-off process, thereby making it possible to reduce the wiring material to be discarded. In addition, a wiring pattern can be manufactured by a so-called Roll to Roll method of continuously manufacturing a wiring pattern on the substrate 1 formed in a roll shape, and simplification of the manufacturing process can be expected.

### Third Embodiment

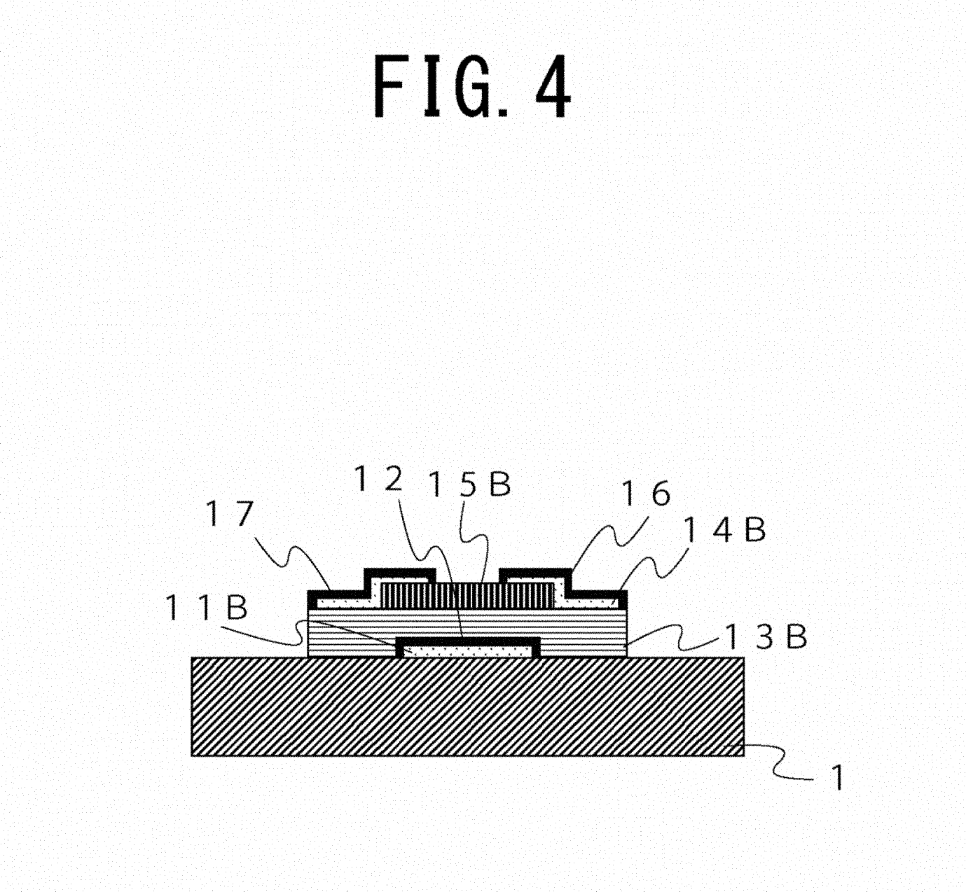

FIG. 4 is a diagram illustrating an example of a transistor according to a third embodiment. According to the second embodiment, a so-called bottom contact-type transistor is manufactured which has a source electrode 16 and a drain electrode 17 formed under the organic semiconductor layer 15B. According to the third embodiment, a so-called top contact-type transistor is manufactured by forming the source electrode 16 and the drain electrode 17 on the organic semiconductor layer 15B.

More specifically, after the formation of an insulator layer 13B, the organic semiconductor solution 15A is applied to have an overlap with the insulator layer 13B, thereby providing an organic semiconductor layer 15B. Next, the plating base layer solution 14A is applied to have an overlap with the organic semiconductor layer 15B, and the plating base layer solution 14A is selectively cured with the use of the mask 21, thereby providing a plating base layer 11B. It is to be noted that it is preferable to use, for the plating base layer solution 14A for use herein, a base layer solution through the use of a water-soluble photosensitive resin so as not to apply a load to the organic semiconductor layer 15B.

Next, at least a part of the resin in the plating base layer 11B is removed by a method such as irradiation with the plasma 23. Thereafter, a plating metal is deposited on the surface of the catalyst for electroless plating in the plating base layer 11B, thereby providing metal wirings.

As described above, according to the present embodiment, a wiring pattern can be obtained which is more preferred in the case of use for a conductive film or a transistor.

### Fourth Embodiment

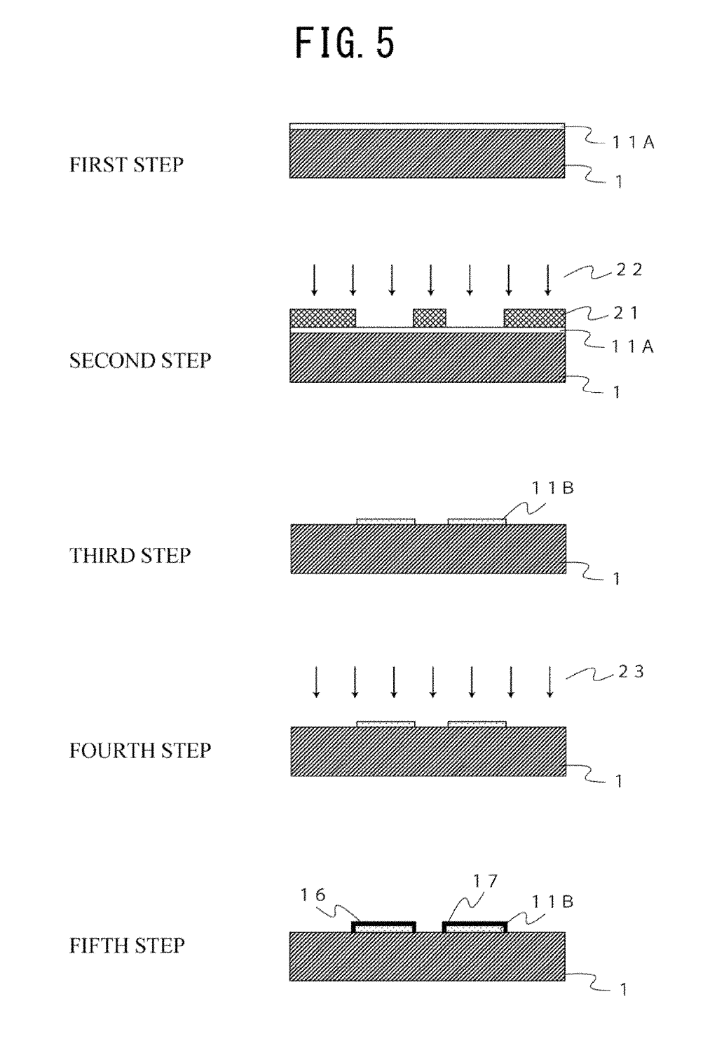

Next, a fourth embodiment will be described. In the second and third embodiments, the processes for manufacturing so-called bottom gate-type transistors with the gate electrodes formed under the source electrodes 16 and the drain electrode 17 have been described. In this embodiment, a process for manufacturing a so-called top gate-type transistor with a gate electrode formed on a source electrode 16 and a drain electrode 17 by using the same materials as in the second and third embodiments will be described with reference to FIGS. 5 to 7.

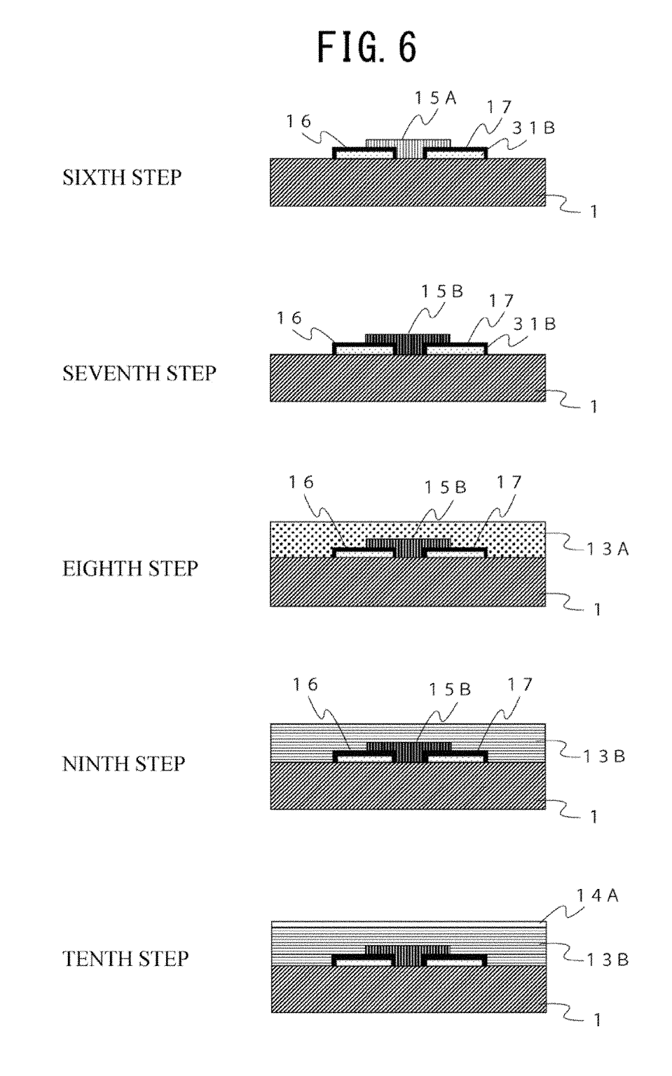

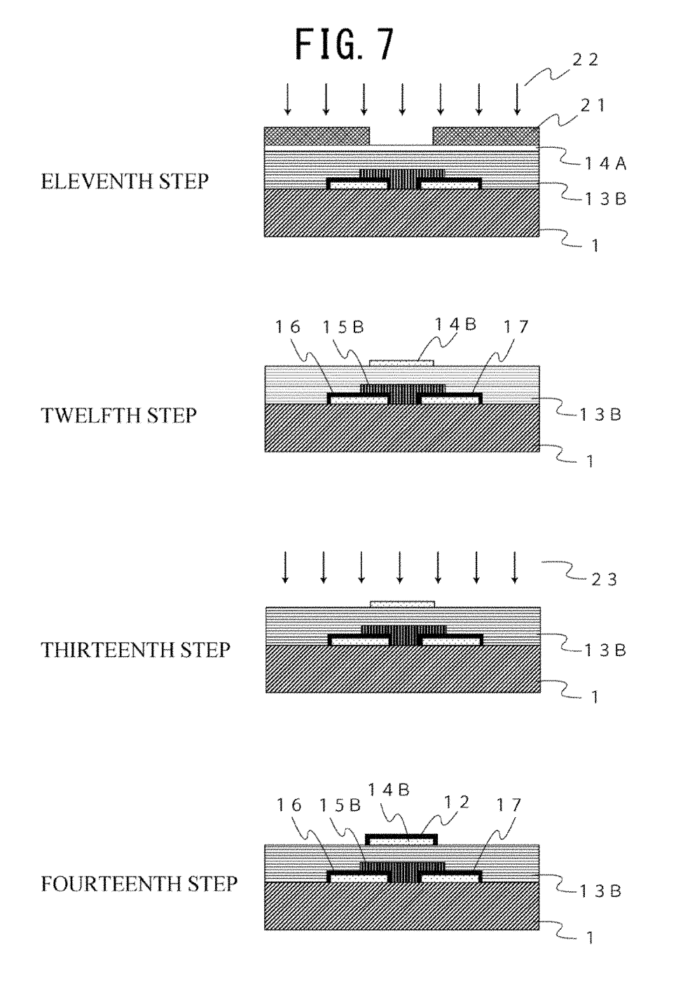

FIG. 5 is a cross-sectional view (part 1) for explaining an example of a method for manufacturing a transistor according to the fourth embodiment, FIG. 6 is a cross-sectional view (part 2) for explaining an example of the method for manufacturing a transistor according to the fourth embodiment, and FIG. 7 is a cross-sectional view (part 3) for explaining an example of the method for manufacturing a transistor according to a fourth embodiment.

(First Step) to (Fifth Step)

In the (first step) to (fifth step), a wiring pattern is formed in the same manner as in the (first step) to (fifth step) according to the first embodiment. It is to be noted that on the substrate 1 shown in the (fifth step) of FIG. 5, two electrodes are formed. According to the present embodiment, the plating base layer solution 11A is selectively cured so that the plating base layer 11B serves as a base film for forming the source electrode 16 and the drain electrode 17. Thereafter, electroless plating is performed to form wirings on the plating base layer 11B, thereby providing a source electrode 16 and a drain electrode 17. It is to be noted that as in the above-described embodiments, the source electrode 16 and the drain electrode 17 may be metal wirings coated with gold.

(Sixth Step)

Next, a solution 15A containing a semiconductor material is applied between the source electrode 16 and the drain electrode 17.

(Seventh Step)

Next, the solvent in the solution 15A containing the semiconductor material is evaporated to obtain the organic semiconductor layer 15B.

(Eighth Step)

Next, an insulator layer solution 13A is applied onto the substrate 1.

(Ninth Step)

Next, the insulator layer solution 13A applied in the eighth step is irradiated with ultraviolet rays and thus cured, thereby providing an insulator layer 13B. While an example of irradiating the entire surface of the applied insulator layer solution 13A with ultraviolet rays has been described herein, an insulator layer 13B that has a desired pattern may be obtained by irradiation with ultraviolet rays through the use of a mask as in the (seventh step) and (eight step) of the second embodiment.

(Tenth Step) to (Fourteenth Step)

Next, the plating base layer solution 14A is applied to have an overlap with the insulator layer 13B. In the (tenth step) to (fourteenth step), a wiring pattern is formed in the same manner as in the (first step) to (fifth step) according to the first embodiment, and as a result of the (fourteenth step), a top gate-type transistor can be obtained which has a gate electrode disposed on the source electrode 16 and the drain electrode 17.

### Example 1

A plating wiring was manufactured by the method for manufacturing a wiring pattern as shown in FIG. 1. First, as the substrate 1, a PET film (Cosmoshine A-4100 (without coating): Toyobo Co., Ltd.) was prepared. In addition, a water-soluble photosensitive resin (BIOSURFINE-AWP-MRH (Toyobo Co., Ltd.)) as a photosensitive resin used for the plating base layer 11B, and a nano-Pd dispersion with fine particles of palladium (Pd) as a catalyst for electroless plating dispersed (Pd concentration 10 mM: manufactured by Renaissance Energy Research Co., Ltd.) were each prepared. The plating base layer solution 11A was prepared by mixing the BIOSURFINE-AWP-MRH, the nano-Pd dispersion, and water at 1:1:1 in ratio by weight.

Next, in order to improve the adhesion between the substrate 1 and the plating base layer formed on the substrate 1, the substrate 1 was irradiated with plasma 23 using an oxygen gas under atmospheric pressure. Thereafter, the plating base layer solution 11A was applied to the substrate 1 by spin coating. The conditions for the spin coating were 30 seconds at 2000 rpm.

Next, the substrate 1 was heated at 60° C. for 3 minutes. Thereafter, the substrate 1 was irradiated with ultraviolet rays 22 through the mask 21 at 24 mJ/cm². Next, the substrate 1 was immersed in pure water, and subjected to ultrasonic treatment at 28 kHz for 1 minute, thereby removing the unexposed part.

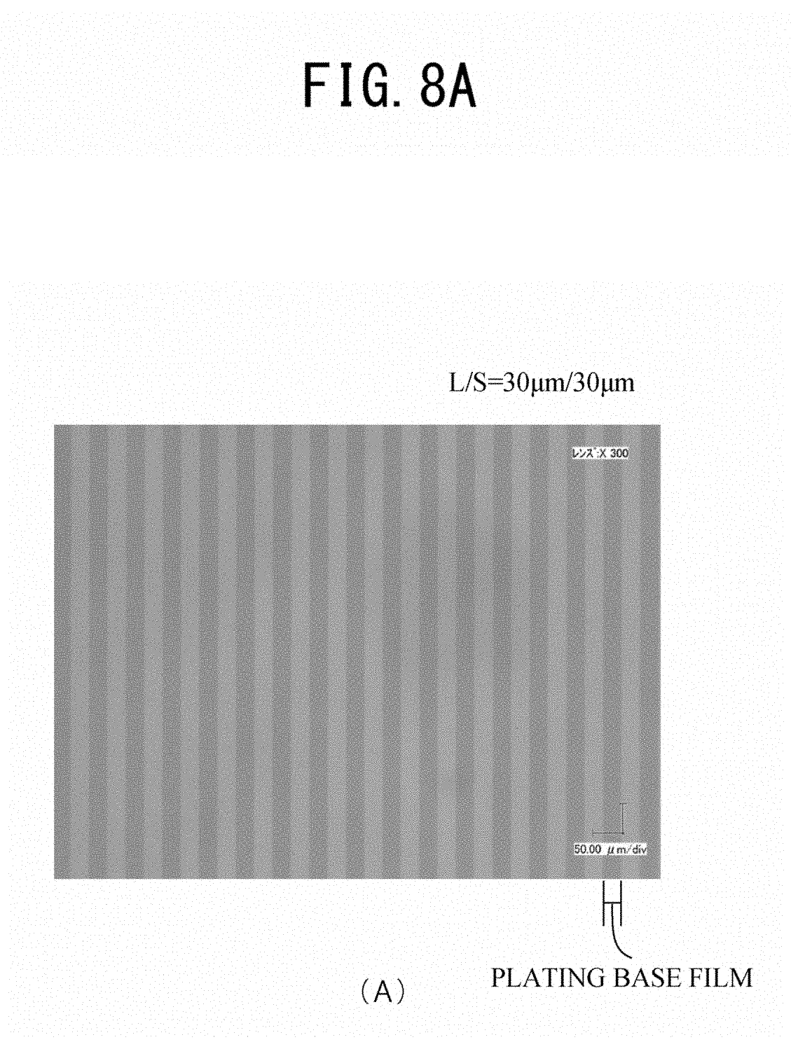

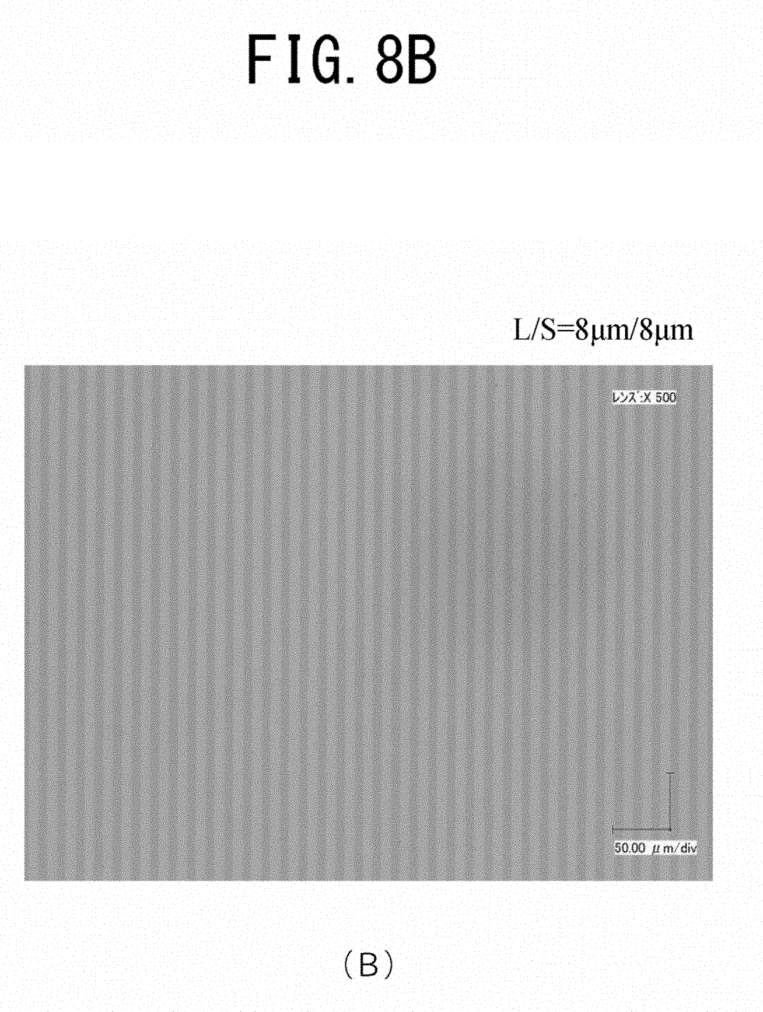

FIG. 8A and FIG. 8B is a diagram showing optical microscopic images of the plating base layer 11B according to Example 1. FIG. 8A is a diagram showing a pattern with L/S=30 μm/30 μm, and FIG. 8B is a diagram showing a pattern with L/S=8 μm/8 μm. The dark colored part refers to the plating base film, and the light colored part refers to the wiring part. It has been confirmed that even a fine pattern with L/S=8 μm/8 μm is successfully drawn.

Next, the substrate 1 was subjected to a plasma treatment with the use of an oxygen gas under an atmospheric pressure, thereby removing the resin at the surface layer of the plating base layer 11B. Thereafter, the substrate 1 was immersed in pure water, and subjected to ultrasonic treatment at 28 kHz for 1 minute. Next, the substrate 1 was immersed in an electroless NiP plating bath (Melplate NI-867: manufactured by Meltex Inc.) for 40 seconds.

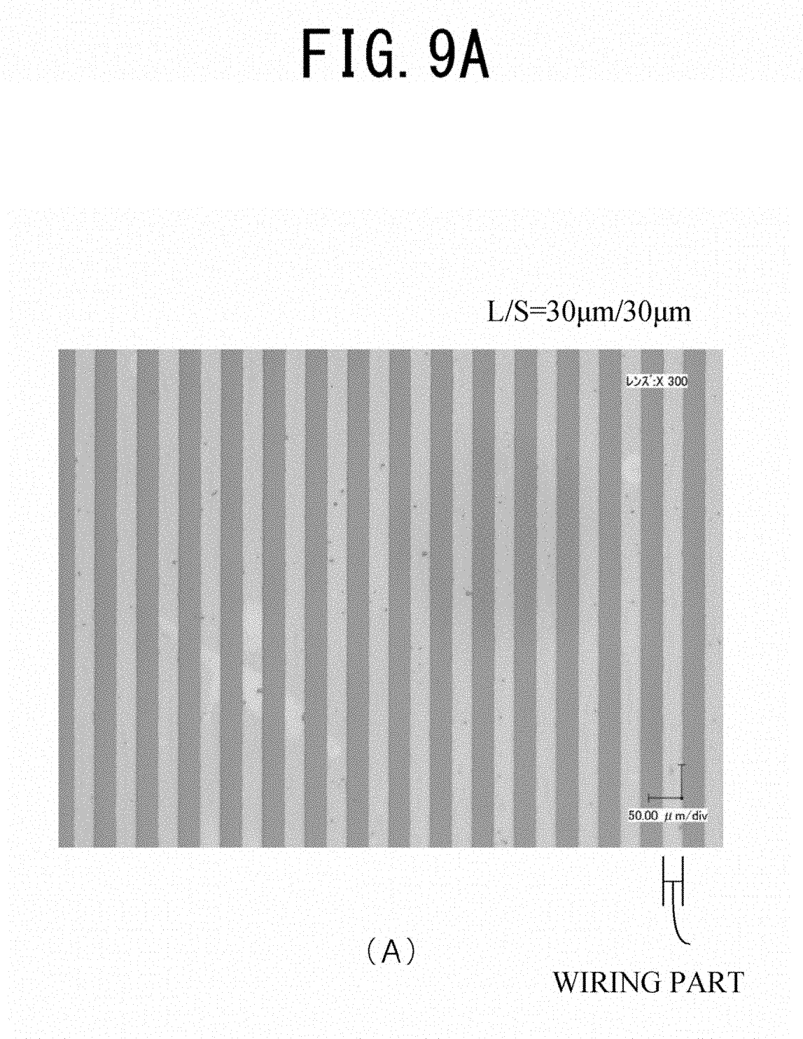

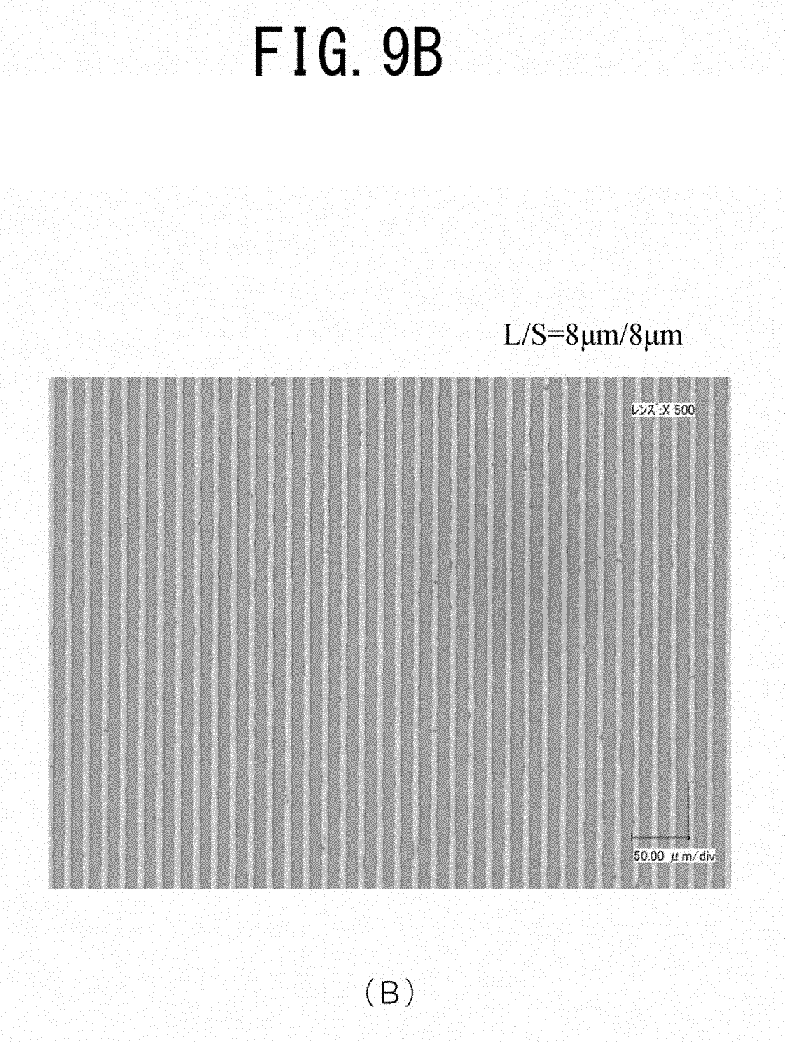

FIG. 9A and FIG. 9B is a diagram showing optical microscopic images of the plated wiring part according to Example 1. FIG. 9A is a diagram showing a pattern with L/S=30 μm/30 μm, and FIG. 9B is a diagram showing a pattern with L/S=8 μm/8 μm. In both FIG. 9A and FIG. 9B, the light colored part refers to the wiring part. It has been found that proper patterning is achieved with clear contrast between the wiring part and the part other than the wiring.

### Comparative Example 1

According to the present comparative example, the plating base layer 11B was subjected to patterning in the same manner as in Example 1, but unlike Example 1, the substrate 1 was not subjected to plasma treatment with oxygen gas. The other steps are the same as in Example 1.

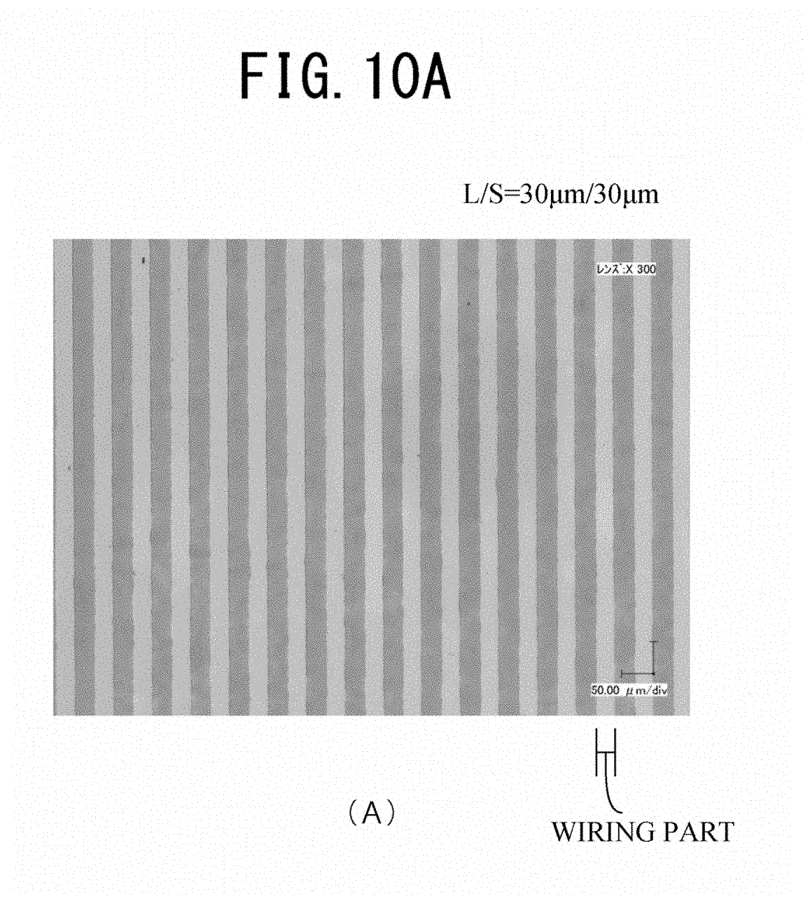

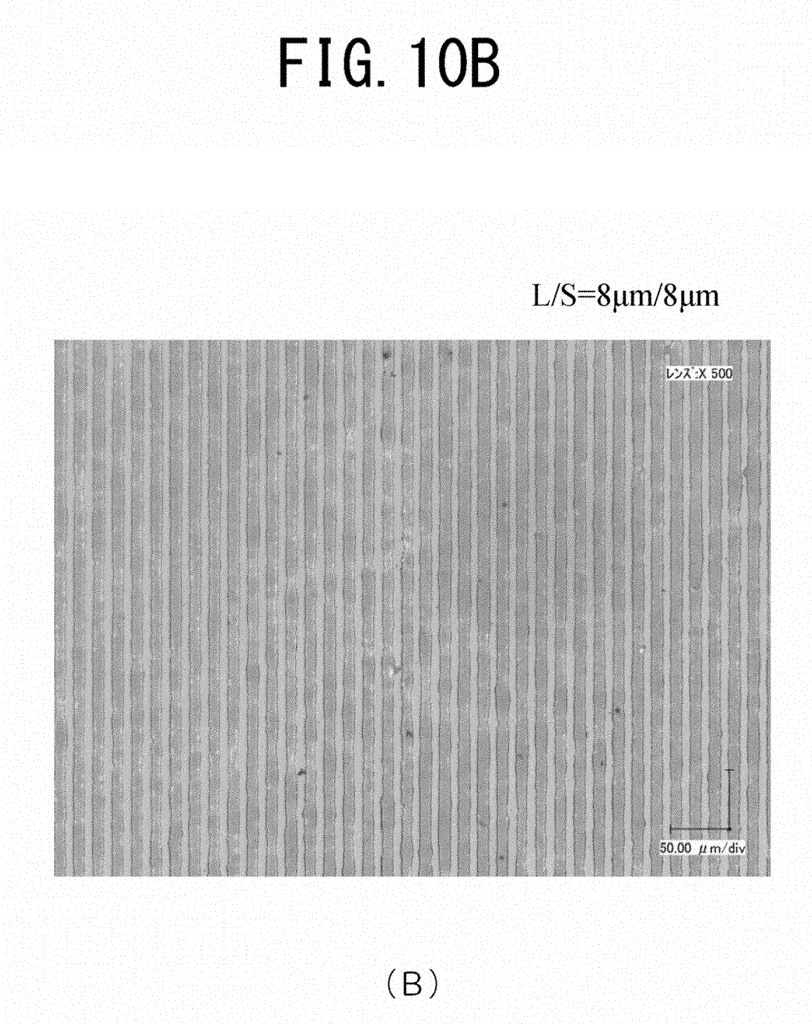

FIG. 10A and FIG. 10B is a diagram showing optical microscopic images of the plated wiring part according to Comparative Example 1. FIG. 10A is a diagram showing a pattern with L/S=30 μm/30 μm, and FIG. 10B is a diagram showing a pattern with L/S=8 μm/8 μm, and in both FIG. 10A and FIG. 10B, the light colored part refers to the wiring part. As is particularly remarkable in FIG. 10B, the part other than the wiring was partially whitened. This indicates that plating metal is also deposited on the part other than the wiring. As a result, it has been found that proper patterning is not achieved.

### Example 2

According to the present example, the plating base layer 11B was subjected to patterning in the same manner as in Example 1, and unlike in Example 1, the substrate 1 was then immersed in a potassium hydroxide aqueous solution of 0.2 mol/L at 70° C. without carrying out any plasma treatment with oxygen gas. The other steps are the same as in Example 1.

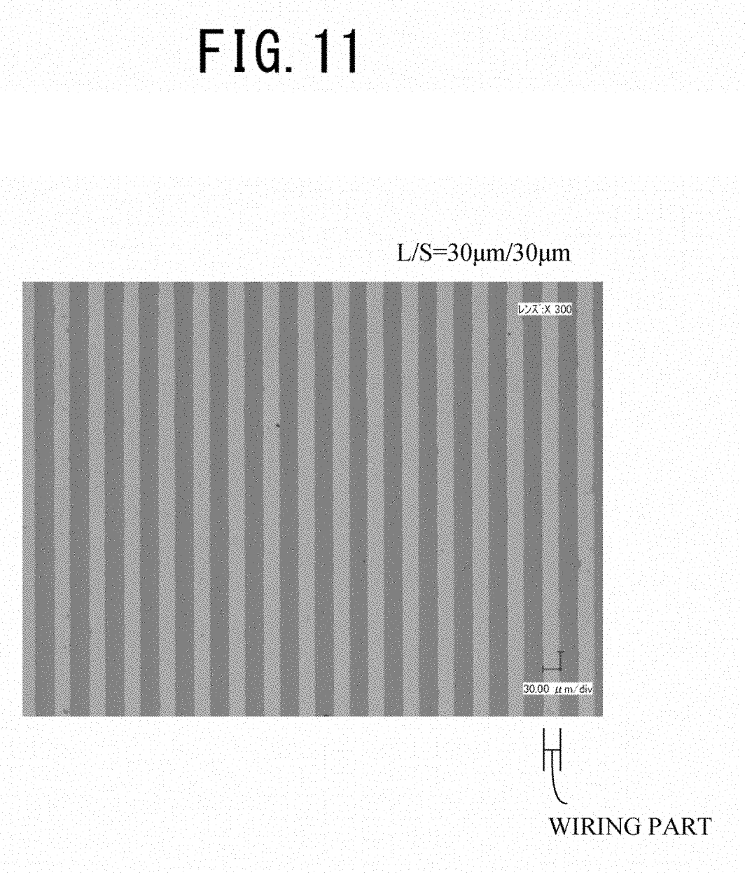

FIG. 11 is a diagram showing an optical microscopic image of the plated wiring part according to Example 2. FIG. 11 shows a pattern with L/S=30 μm/30 μm, where a light colored part is a wiring part. It has been found that with clear contrast between the wiring part and the part other than the wiring, proper patterning is achieved as in the case of carrying out the plasma treatment, even in the case of immersion in the potassium hydroxide solution.

### Example 3

(Formation of Gate Electrode)

In the same manner as in Example 1, a NiP plated wiring was formed on the substrate 1 as a gate electrode. Thereafter, the substrate 1 was heated at 105° C. for 20 minutes in order to remove the moisture provided from the electroless NiP plating bath.

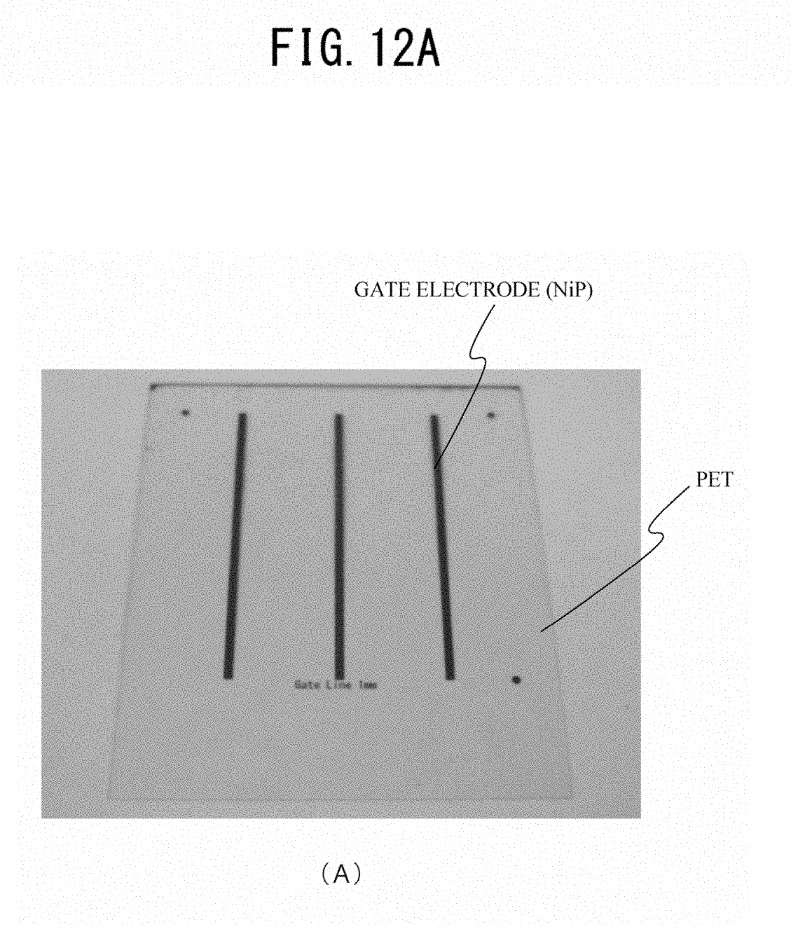

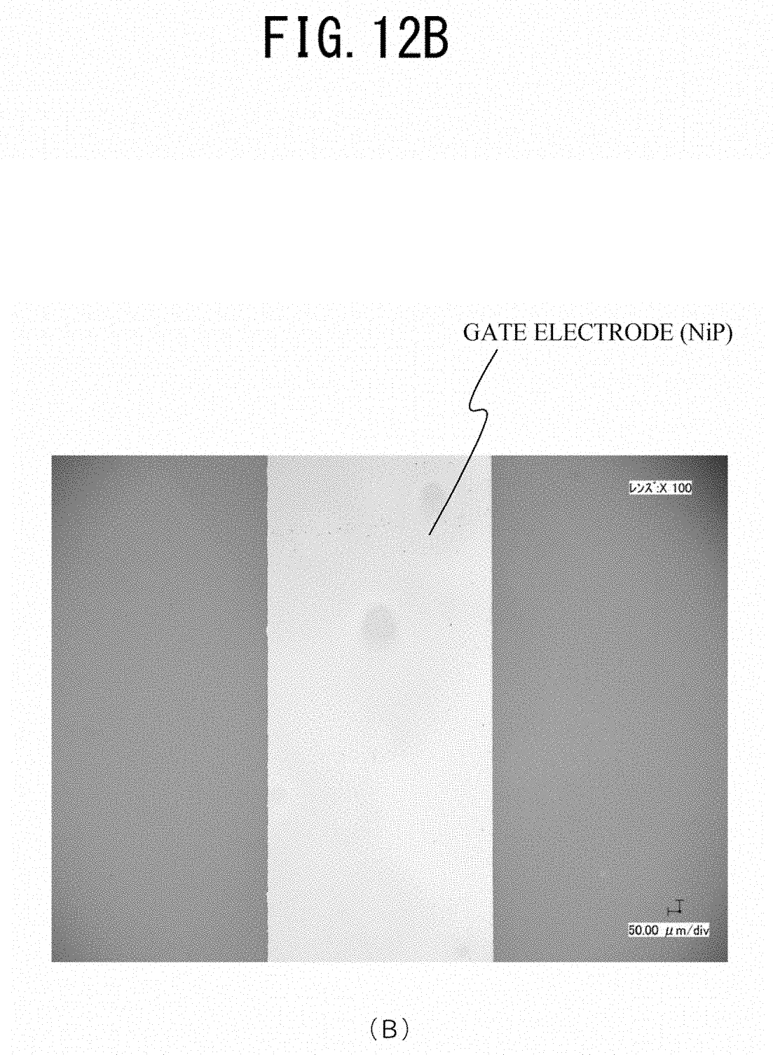

FIG. 12A and FIG. 12B is a diagram showing optical microscopic images of a substrate 1 and a gate electrode according to Example 3. FIG. 12A is a photograph of the substrate 1 with the gate electrode formed according to Example 3. FIG. 12B is an optical microscopic image of the gate electrode. The gate electrode is properly formed on the substrate 1.

(Formation of Insulator Layer 13B)

Next, the substrate 1 was irradiated with plasma using oxygen gas under atmospheric pressure. Next, the insulating film resin solution was applied to the substrate 1 by dip coating. For the insulating film resin solution, an insulating resin material (SU8 3005: manufactured by Nippon Kayaku Co., Ltd.) was diluted twice with cyclohexanone, and used. In addition, the pull-up speed of the dip coating was adjusted to 1 mm/s.

Next, the substrate 1 was heated at 105° C. for 10 minutes. Thereafter, the substrate 1 was irradiated with ultraviolet rays 22 of 200 mJ/cm² through the photomask 21, and heated at 105° C. for 60 minutes. Then, the substrate 1 was impregnated with PGMEA (propylene glycol 1-monomethyl ether 2-acetate) to dissolve a region of the insulator layer 13B which was unexposed to the ultraviolet ray 22. Thereafter, the substrate 1 was heated at 105° C. for 30 minutes to form an insulator layer 13B of 1 μm in thickness.

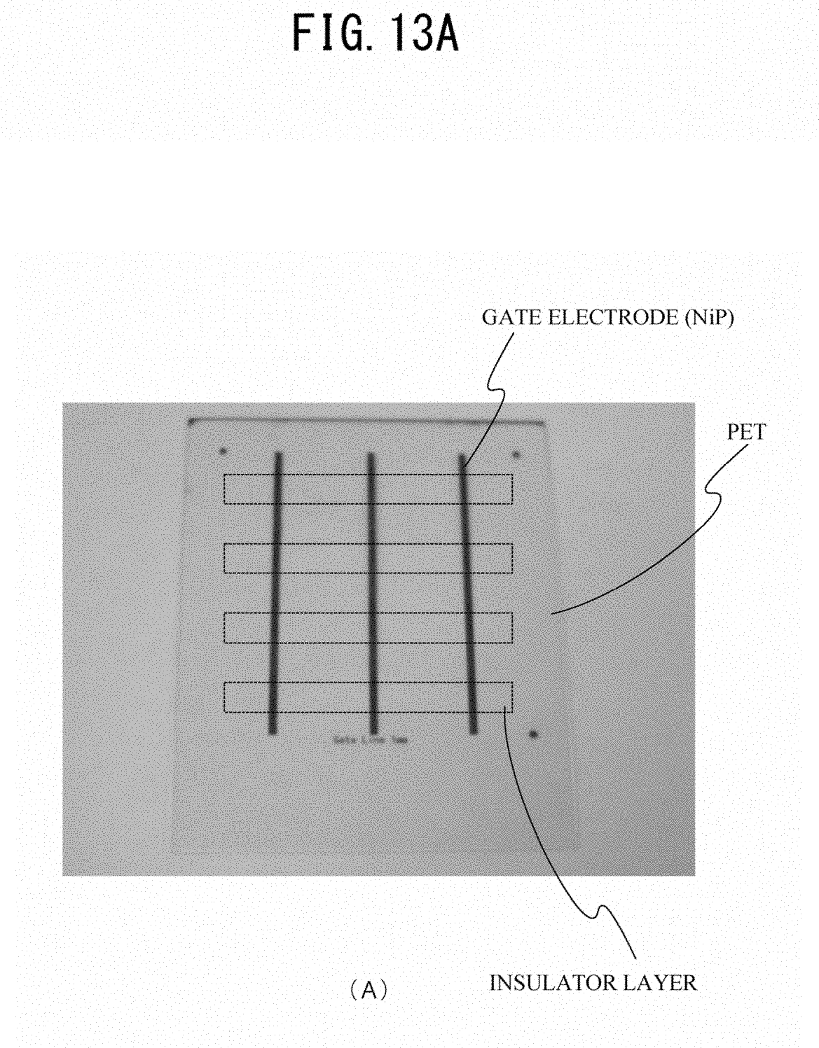

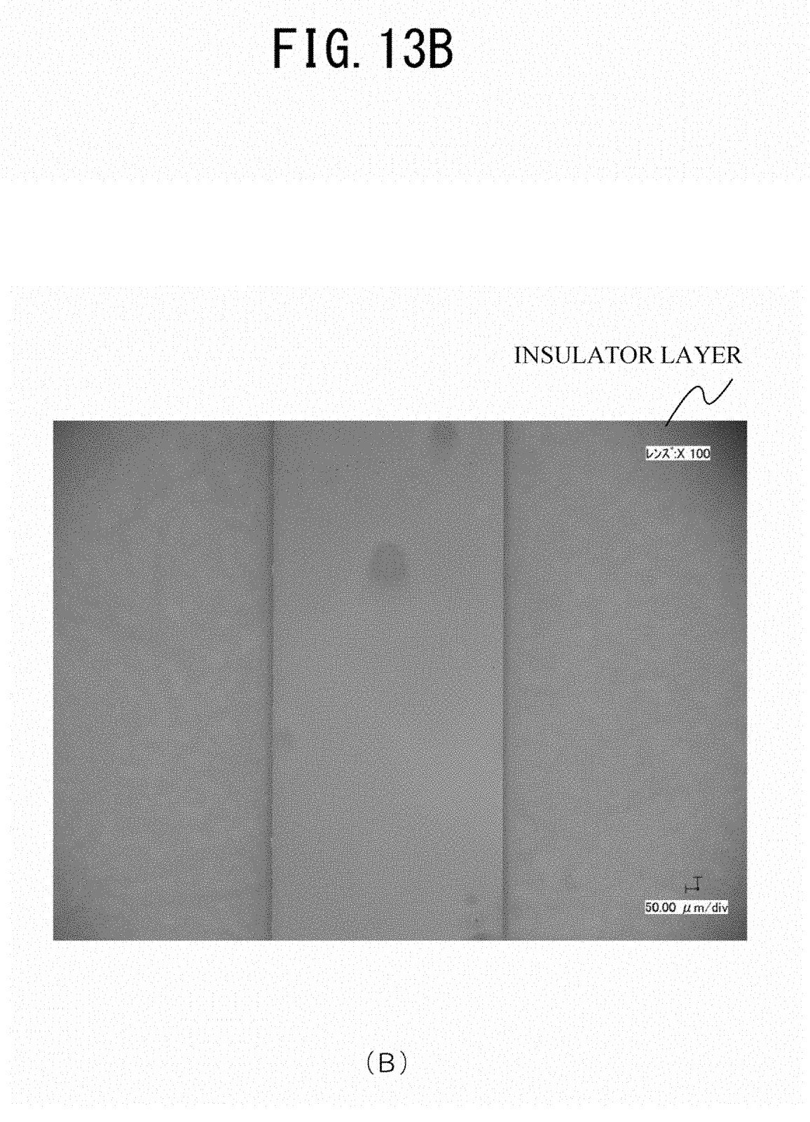

FIG. 13A and FIG. 13B is a diagram showing the substrate 1 after the formation of the insulator layer 13B according to Example 3, and an optical microscopic image of the substrate 1. FIG. 13A is a photograph of the substrate 1 after the formation of the insulator layer 13B, where regions surrounded by dotted lines refer to regions with the insulator layer 13B formed. It is to be noted that the dotted line is superimposed ex post facto on the photograph in order to clarify the boundary between the region where the insulator layer 13B is formed and the other region, but not any part of the image. FIG. 13B is an optical microscopic image of the substrate 1 after the formation of the insulator layer 13B.

(Formation of Source Electrode 16 and Drain Electrode 17)

After forming a plated wiring of NiP on the insulator layer 13B in the same manner as in Example 1, the substrate 1 was impregnated with a substitution Au plating bath (SuperMex #255: manufactured by N.E. Chemcat Corporation) for 1 minute. Then, the substrate 1 was impregnated with a reduced Au plating bath (SuperMex # 880: manufactured by N.E. Chemcat Corporation) for 1 minute. Thereafter, in order to remove moisture, the substrate 1 was dried at 105° C. for 60 minutes.

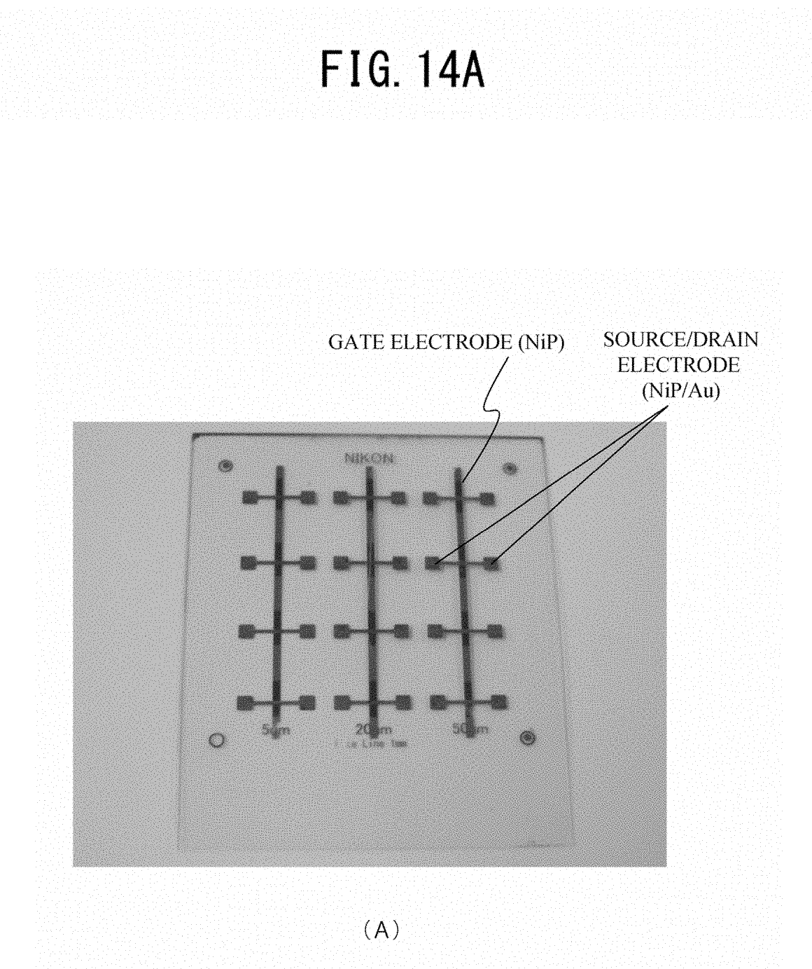

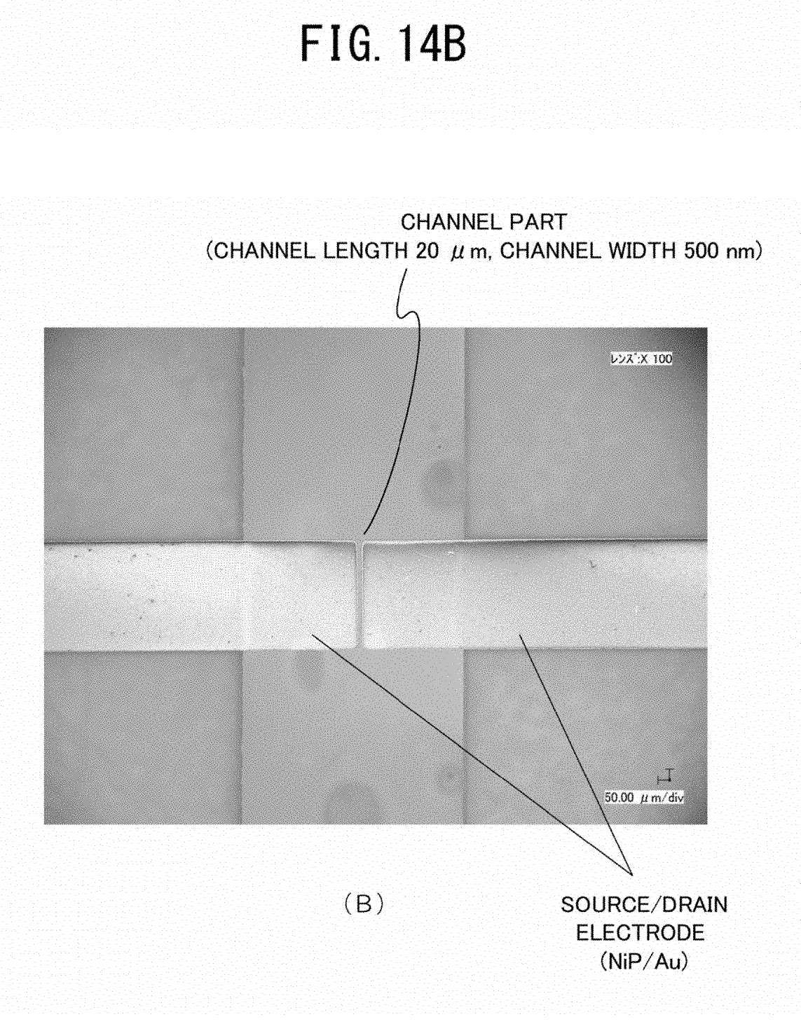

FIG. 14A and FIG. 14B is a diagram showing the substrate 1 after the formation of a source electrode 16 and a drain electrode 17 according to Example 3, and an optical microscopic image of the electrodes. FIG. 14A is a photograph of the substrate 1 after the formation of the source electrode 16 and the drain electrode 17, and FIG. 14B is an optical microscopic image of the electrodes. The source electrode 16 and the drain electrode 17 were formed so that the channel length was 20 μm, whereas the channel width was 500 nm.

(Formation of Organic Semiconductor Layer 15B)

Next, a 2 wt % TIPS pentacene toluene solution was drop-deposited on the channel region, thereby fabricating an organic transistor.

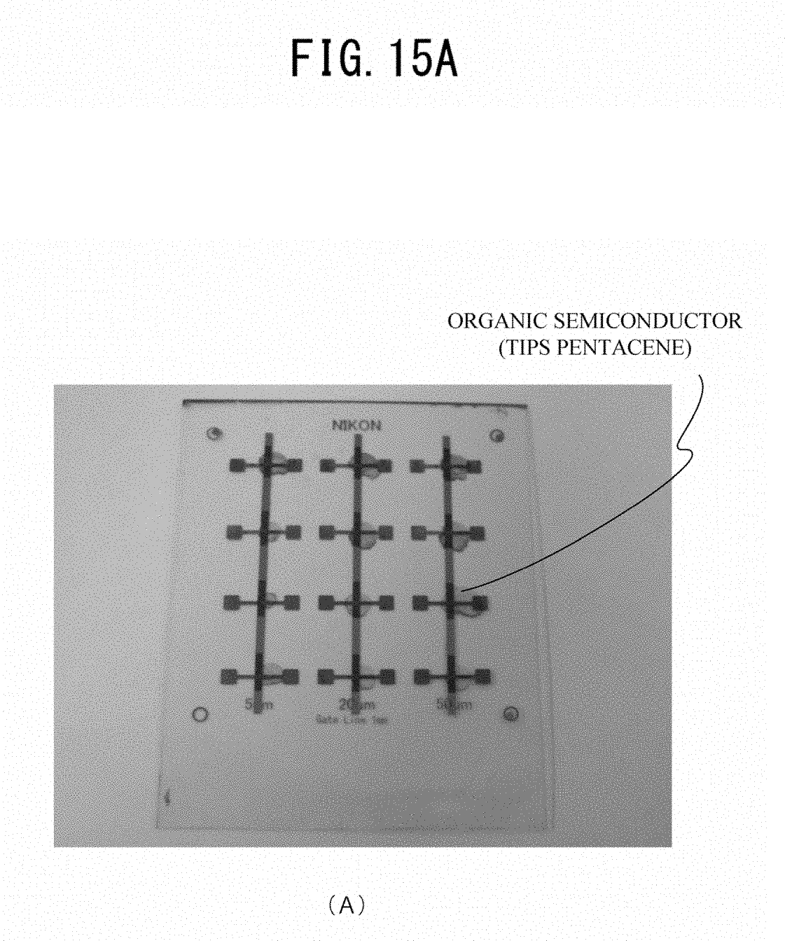

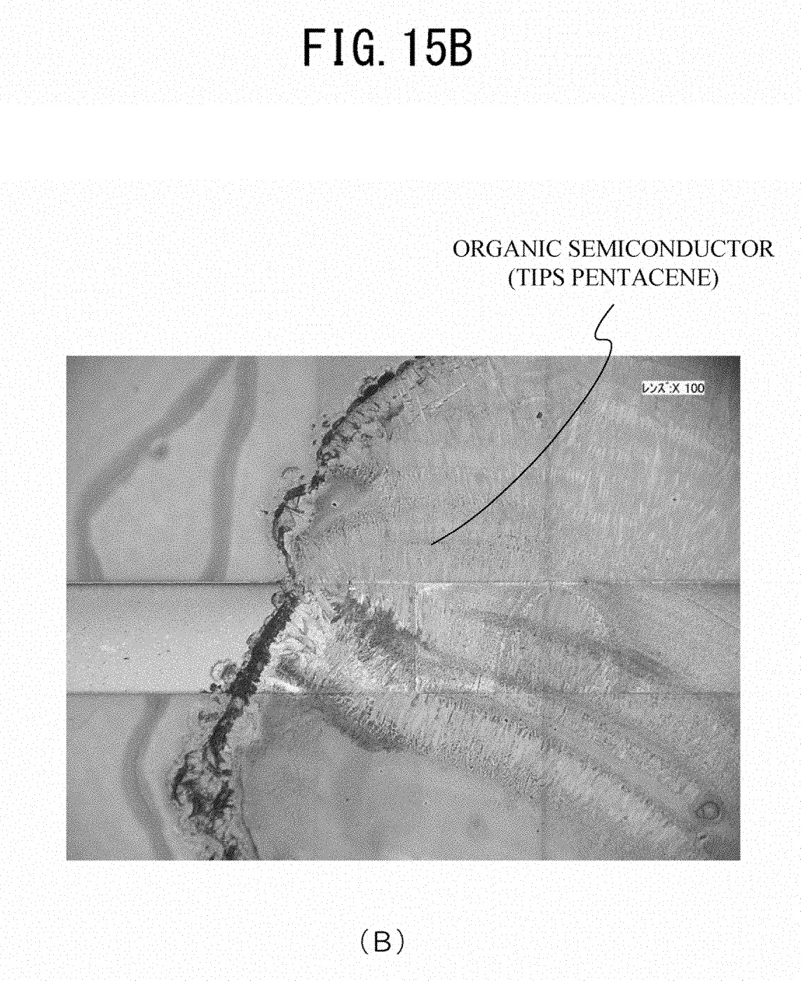

FIG. 15A and FIG. 15B is a diagram showing the substrate 1 after the formation of the organic semiconductor layer 15B according to Example 3, and an optical microscopic image of the substrate 1. FIG. 15A is a photograph of the substrate 1 after the formation of the organic semiconductor layer 15B, and FIG. 15B is an optical microscopic image of the organic semiconductor layer 15B.

It has been found that the organic semiconductor layer 15B is formed on the channel region.

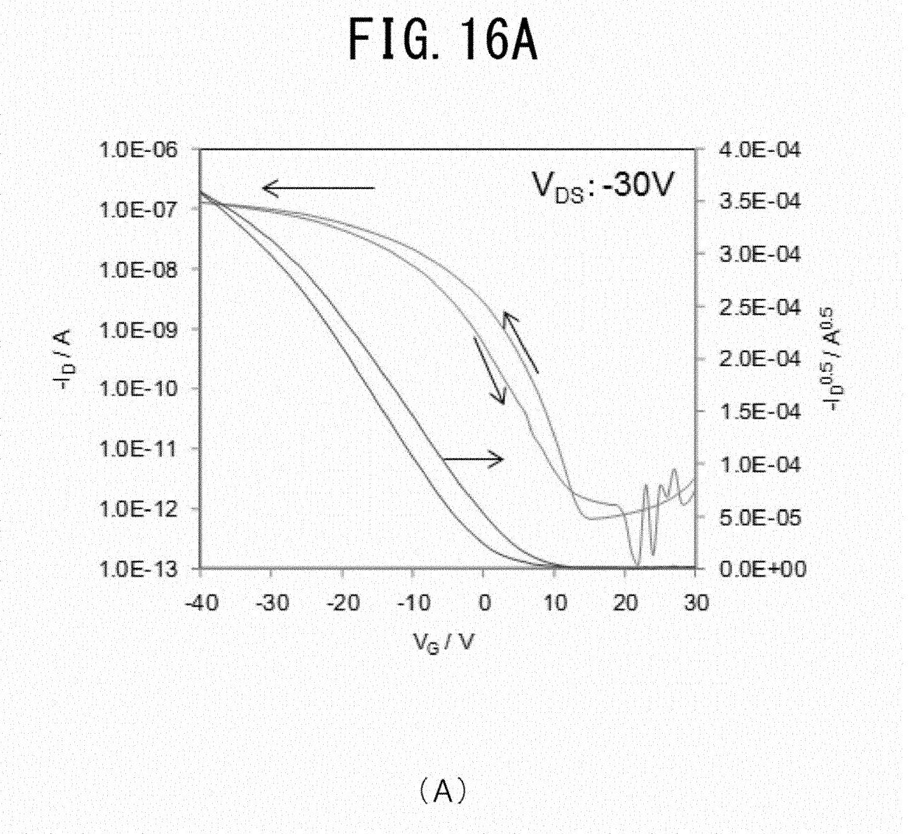

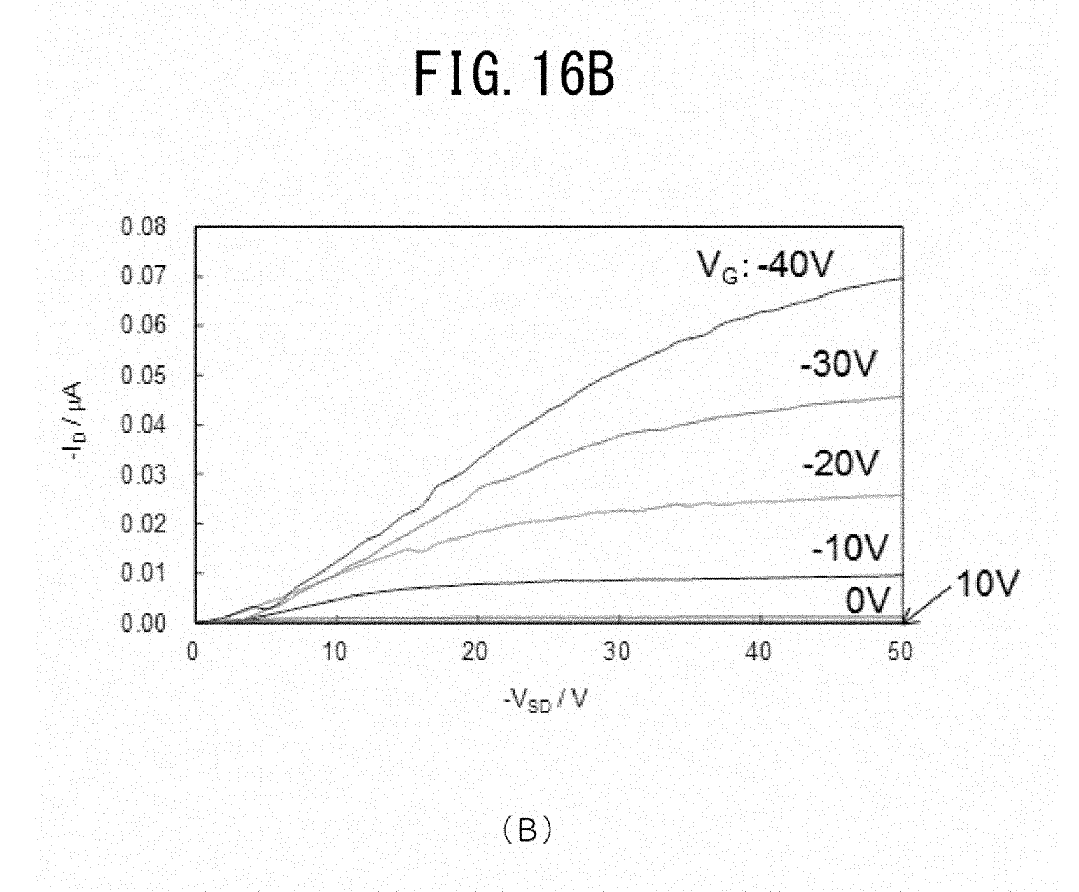

FIG. 16A and FIG. 16B is a diagram showing characteristic evaluations of a transistor according to Example 3. Transistor characteristics were evaluated with the use of a semiconductor parameter analyzer (4200-SCS: manufactured by TFF Keithley Instruments Inc.). FIG. 16A is a diagram showing transfer characteristics of the bottom-gate and bottom-contact type organic transistor fabricated in Example 3, and FIG. 16B is a diagram showing output characteristics of the transistor. In addition, this transistor exhibits relatively favorable characteristics of mobility: 1.2×10⁻³ cm²/Vs and On/Off ratio: 1.9×10⁵.

(Evaluation)

As described above, the wiring patterns and the transistor have been successfully fabricated by electroless plating without using any lift-off process. According to this embodiment, all of the steps can be carried out under atmospheric pressure. In addition, it is possible to perform any of the processes under a temperature around 100° C., thus allowing, even when PET is used for the substrate 1, a preferred transistor to be fabricated at a temperature equal to or lower than the softening point of the substrate 1. In addition, highly accurate wirings pattern can be obtained because patterning is performed with the use of light.

### Reference Signs List

1 substrate
11A plating base layer solution
11B plating base layer
12 electroless plating layer
13A insulator layer solution
13B insulator layer
14A plating base layer solution
14B plating base layer
15A organic semiconductor solution
15B organic semiconductor layer
16 source electrode
17 drain electrode
21 mask
22 ultraviolet ray
23 plasma

1. A method for manufacturing a wiring pattern, the method comprising:
a base layer forming step of forming an base layer comprising a catalyst for electroless plating and a resin;
a surface layer removing step of removing at least a part of a surface layer of the base layer; and
a plating layer forming step of performing electroless plating and forming a plating layer on the base layer subjected to the surface layer removing step, wherein a precursor for the resin is water-soluble.

2. The method for manufacturing a wiring pattern according to claim 1, wherein,
in the base layer forming step, the base layer is formed by applying a solution comprising the catalyst for electroless plating and the precursor for the resin, and curing the precursor for the resin into a predetermined pattern.

3. The method for manufacturing a wiring pattern according to claim 2, wherein
the precursor for the resin is cured by irradiation with light comprising light with a predetermined wavelength.

4. The method for manufacturing a wiring pattern according to claim 3, wherein
the precursor for the resin is cured by irradiation with light comprising the light with the predetermined wavelength through a mask with an opening corresponding to the predetermined pattern.

5. The method for manufacturing a wiring pattern according to claim 1, wherein
in the surface layer removing step, a surface of the base layer is irradiated with plasma.

6. The method for manufacturing a wiring pattern according to claim 1, wherein
in the surface layer removing step, an alkaline solution is brought into contact with the base layer.

7. The method for manufacturing a wiring pattern according to claim 1, wherein
the catalyst for electroless plating comprises at least one of palladium, copper, nickel, iron, platinum, and silver.

8. The method for manufacturing a wiring pattern according to claim 1, wherein
in the base layer forming step, the base layer is formed on a substrate comprising a resin material.

9. The method for manufacturing a wiring pattern according to claim 8, wherein
the base layer forming step, the surface layer removing step, and the plating layer forming step are performed at a temperature lower than a softening point of the substrate.

10. A method for manufacturing a conductive film, wherein
the conductive film is manufactured by using the method for manufacturing a wiring pattern according to claim 1.

11. A method for manufacturing a transistor comprising a gate electrode, a source electrode, a drain electrode, a semiconductor layer, and a gate insulating layer, wherein
at least one of the gate electrode, the source electrode, and the drain electrode is manufactured by the method for manufacturing a wiring pattern according to claim 1.
